(19) United States
(12) Patent Application Publication
(10) Pub. No.: US 2019/0181172 A1
(43) Pub. Date: Jun. 13, 2019

(54) FAN-OUT SENSOR PACKAGE

(71) Applicant: SAMSUNG ELECTRO-MECHANICS CO., LTD., Suwon-si (KR)

(72) Inventors: Jong Rok KIM, Suwon-Si (KR); Yong Ho BAEK, Suwon-Si (KR); Jung Hyun CHO, Suwon-Si (KR); Min Keun KIM, Suwon-Si (KR); Jung Chul GONG, Suwon-Si (KR); Young Sik HUR, Suwon-Si (KR)

(21) Appl. No.: 15/958,625

(22) Filed: Apr. 20, 2018

(30) Foreign Application Priority Data
Dec. 7, 2017 (KR) 10-2017-0167533

(51) Int. Cl. H01L 27/146; H01L 23/00; H01L 25/065; H01L 23/31

(52) U.S. Cl. CPC H01L 27/14625; H01L 2224/02379; H01L 27/14618; H01L 27/14643; H01L 27/14689; H01L 27/14685; H01L 24/17; H01L 24/14; H01L 25/0657; H01L 23/3128; H01L 2924/15311; H01L 2924/15313; H01L 2225/06513; H01L 2225/06586; H01L 2224/0401; H01L 24/09

(57) ABSTRACT

A fan-out sensor package includes: an image sensor chip including an integrated circuit (IC) for an image sensor having a first surface having first connection pads disposed thereon, a second surface opposing the first surface and having second connection pads disposed thereon, and through-silicon-vias (TSVs) penetrating between the first surface and the second surface and electrically connecting the first and second connection pads to each other and an optical portion disposed on the first surface of the IC for an image sensor and having a plurality of lens layers; an encapsulant covering at least portions of the second surface of the IC for an image sensor; a redistribution layer disposed on the encapsulant; and vias penetrating through at least portions of the encapsulant and electrically connecting the redistribution layer and the second connection pads to each other.

### CROSS-REFERENCE TO RELATED APPLICATION(S)

This application claims benefit of priority to Korean Patent Application No. 10-2017-0167533 filed on Dec. 7, 2017 in the Korean Intellectual Property Office, the disclosure of which is incorporated herein by reference in its entirety.

### TECHNICAL FIELD

The present disclosure relates to a fan-out sensor package in which an image sensor chip is packaged in a fan-out form.

### BACKGROUND

In accordance with a recent tendency to apply a full panel display to a front surface of a smartphone, it has been inevitable to move a position of a capacitive fingerprint sensor disposed on a front surface of an existing smartphone. For example, the capacitive fingerprint sensor has been moved to a rear surface or a side surface of the smartphone. However, in this case, a design issue has been continuously raised. Therefore, demand for optical fingerprint sensor packaging technology capable of disposing the fingerprint sensor below a display panel has increased.

### SUMMARY

An aspect of the present disclosure may provide an optical sensor package in which assembling yield improvement and sensing characteristic improvement may be expected since a process of attaching an assembling the sensor package to a display is easy and thinness and miniaturization of the sensor package may be expected.

According to an aspect of the present disclosure, a fan-out sensor package may be provided, in which an optical portion and an integrated circuit (IC) for an image sensor are bonded to each other to implement one image sensor chip, a redistribution design is promoted using through-silicon-vias (TSVs), and the image sensor chip is disposed in a through-hole of a core member and is then encapsulated to facilitate a process of attaching and assembling the fan-out sensor package to a display.

According to an aspect of the present disclosure, a fan-out sensor package may include: an image sensor chip including an IC for an image sensor having a first surface having first connection pads disposed thereon, a second surface opposing the first surface and having second connection pads disposed thereon, and TSVs penetrating between the first surface and the second surface and electrically connecting the first and second connection pads to each other and an optical portion disposed on the first surface of the IC for an image sensor and having a plurality of lens layers; an encapsulant covering at least portions of the second surface of the IC for an image sensor; a redistribution layer disposed on the encapsulant; and vias penetrating through at least portions of the encapsulant and electrically connecting the redistribution layer and the second connection pads to each other.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a ball grid array (BGA) substrate and is ultimately mounted on a mainboard of an electronic device;

FIG. 6 is a schematic cross-sectional view illustrating a case in which a fan-in semiconductor package is embedded in a BGA substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a fan-out sensor package;

FIG. 10 is a schematic plan view taken along line I-I′ of the fan-out sensor package of FIG. 9;

FIGS. 11A through 11C are schematic views illustrating lens disposition forms of an optical portion of the fan-out sensor package of FIG. 9;

FIGS. 12A through 12E are schematic views illustrating an example of processes of manufacturing the fan-out sensor package of FIG. 9;

FIG. 13 is a schematic cross-sectional view illustrating another example of a fan-out sensor package;

FIG. 14 is a schematic cross-sectional view illustrating another example of a fan-out sensor package;

FIG. 15 is a schematic cross-sectional view illustrating another example of a fan-out sensor package;

FIG. 16 is a schematic cross-sectional view illustrating another example of a fan-out sensor package;

FIG. 17 is a schematic cross-sectional view illustrating another example of a fan-out sensor package;

FIG. 18 is a schematic cross-sectional view illustrating another example of a fan-out sensor package; and

FIG. 19 is a schematic cross-sectional view illustrating another example of a fan-out sensor package.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Herein, a lower side, a lower portion, a lower surface, and the like, are used to refer to a direction toward a mounting surface of the fan-out sensor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

Electronic Device

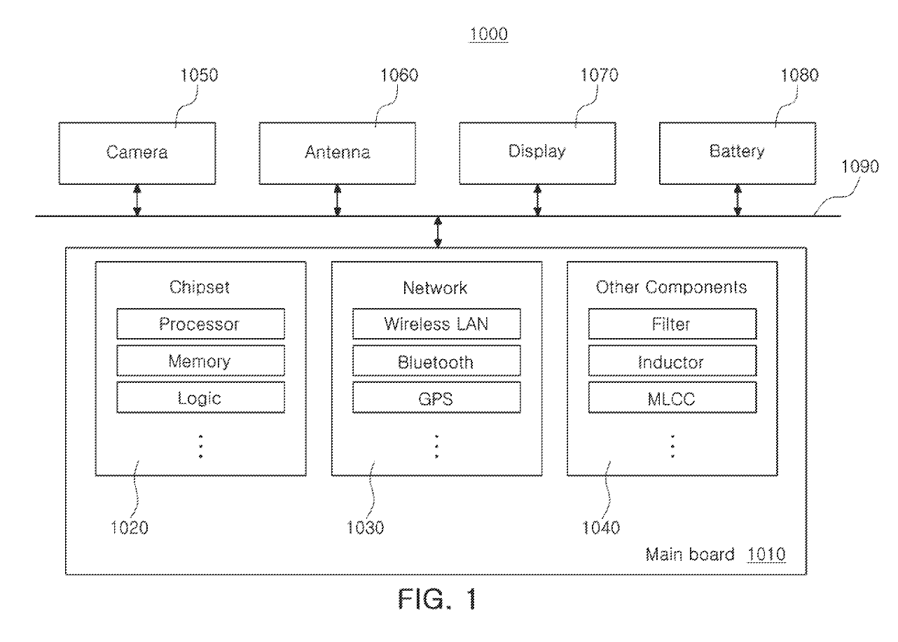

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 maybe combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

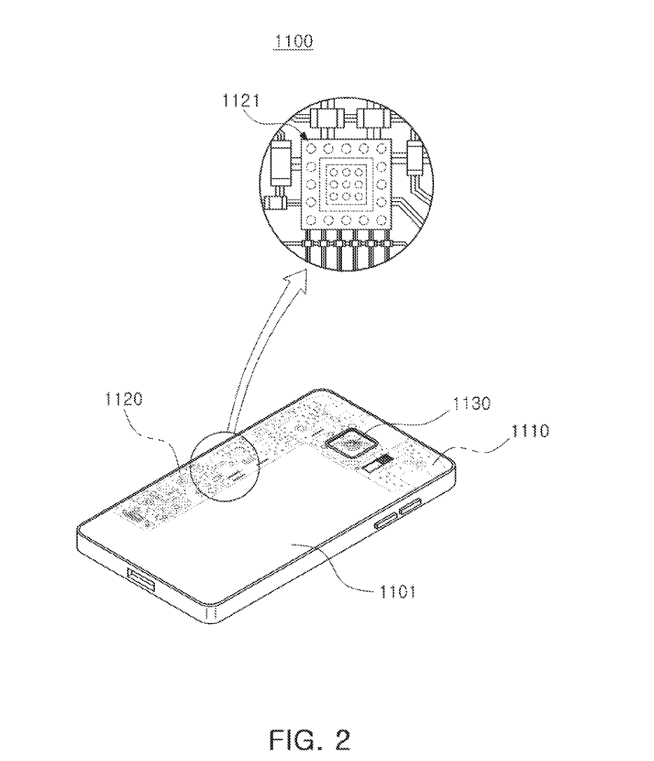

FIG. 2 is a schematic perspective view illustrating an example of an electronic device.

Referring to FIG. 2, an electronic device may be, for example, a smartphone 1100. A mainboard 1110 may be accommodated in a body 1101 of the smartphone 1100, and various electronic components 1120 such as a semiconductor package 1121 may be physically or electrically connected to the mainboard 1110. In addition, other components that may or may not be physically or electrically connected to the mainboard 1110, such as the camera module 1130, may be accommodated in the body 1101. The camera module 1130 may include an image sensor package, and a fan-out sensor package according to the present disclosure may be used in the smartphone. Meanwhile, the electronic device in which the fan-out sensor package according to the present disclosure is used is not limited to the smartphone 1100. That is, the fan-out sensor package according to the present disclosure may also be used in other electronic devices.

Semiconductor Package

A fan-out sensor package according to the present disclosure may be manufactured using technology of a semiconductor package. Generally, numerous fine electrical circuits are integrated in a semiconductor. However, the semiconductor may not serve as a finished semiconductor product in itself, and may be damaged due to external physical or chemical impacts. Therefore, the semiconductor itself may not be used, but may be packaged and used in an electronic device, or the like, in a packaged state.

Here, semiconductor packaging is required due to the existence of a difference in a circuit width between the semiconductor and a mainboard of the electronic device in terms of electrical connections. In detail, a size of connection pads of the semiconductor and an interval between the connection pads of the semiconductor are very fine, but a size of component mounting pads of the mainboard and an interval between the component mounting pads of the mainboard are significantly larger than those of the semiconductor. Therefore, it may be difficult to directly mount the semiconductor on the mainboard, and packaging technology for buffering a difference in a circuit width between the semiconductor and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

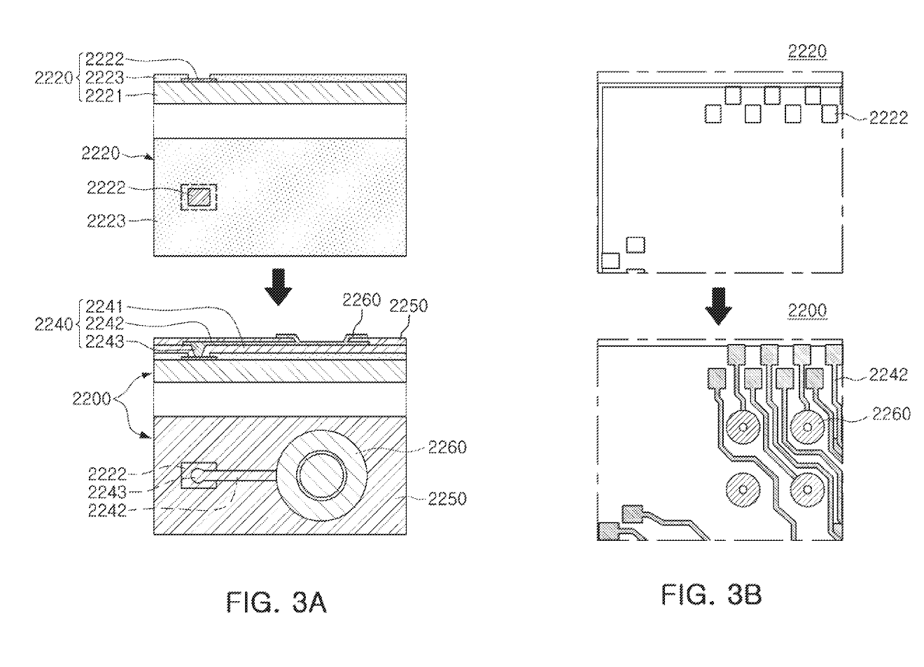

FIGS. 3A and 3B are schematic cross-sectional views illustrating states of a fan-in semiconductor package before and after being packaged.

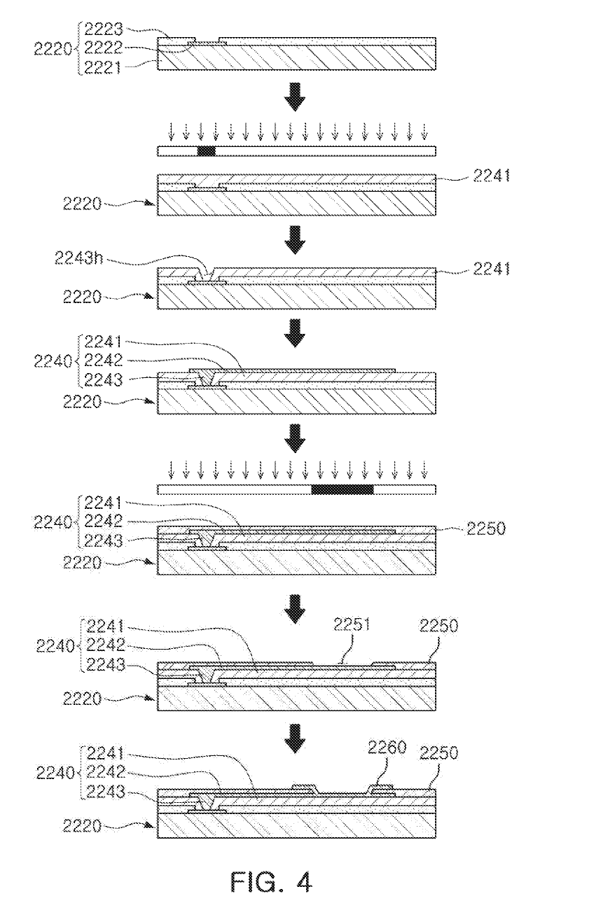

FIG. 4 is schematic cross-sectional views illustrating a packaging process of a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor are disposed inside the semiconductor, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor in the fan-in semiconductor package, the fan-in semiconductor package has significant spatial limitations. Therefore, it is difficult to apply this structure to a semiconductor having a large number of I/O terminals or a semiconductor having a compact size. In addition, due to the disadvantage described above, the fan-in semiconductor package may not be directly mounted and used on the mainboard of the electronic device. The reason is that even in the case in which a size of the I/O terminals of the semiconductor and an interval between the I/O terminals of the semiconductor are increased by a redistribution process, the size of the I/O terminals of the semiconductor and the interval between the I/O terminals of the semiconductor may not be sufficient to directly mount the fan-in semiconductor package on the mainboard of the electronic device.

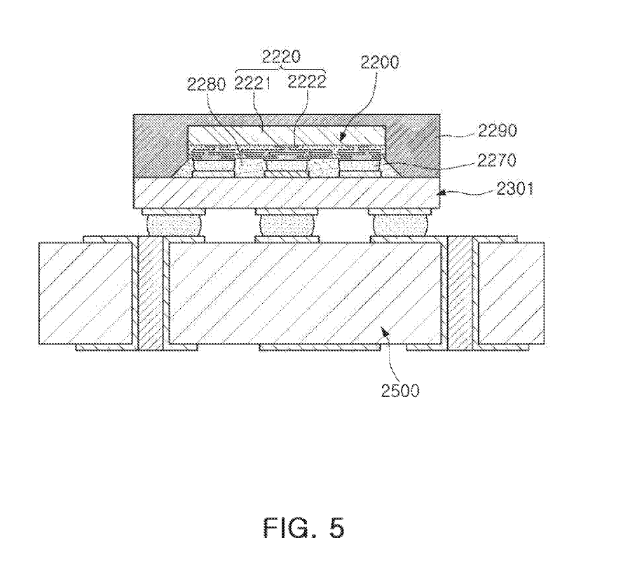

FIG. 5 is a schematic cross-sectional view illustrating a case in which a fan-in semiconductor package is mounted on a ball grid array (BGA) substrate and is ultimately mounted on a mainboard of an electronic device.

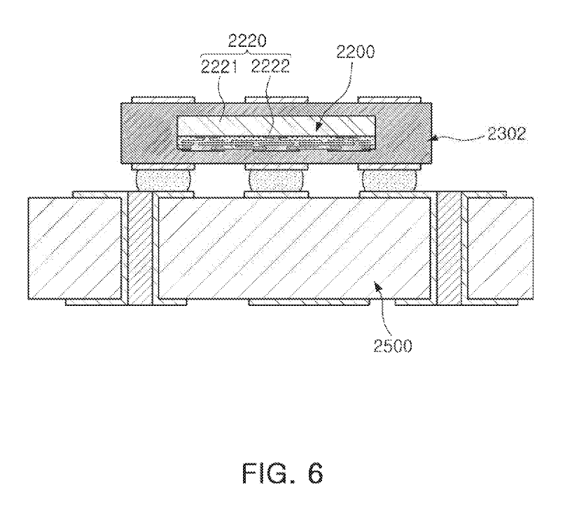

FIG. 6 is a schematic cross-sectional view illustrating a case in which a fan-in semiconductor package is embedded in a BGA substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package maybe mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

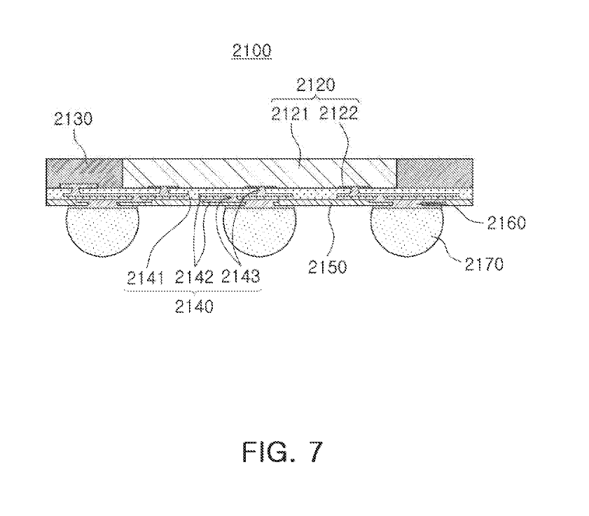

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor are redistributed and disposed outwardly of the semiconductor through the connection member formed on the semiconductor. As described above, in the fan-in semiconductor package, all I/O terminals of the semiconductor need to be disposed inside the semiconductor. Therefore, when a size of the semiconductor is decreased, a size and a pitch of balls need to be decreased, such that a standardized ball layout may not be used in the fan-in semiconductor package. On the other hand, the fan-out semiconductor package has the form in which the I/O terminals of the semiconductor are redistributed and disposed outwardly of the semiconductor through the connection member formed on the semiconductor as described above. Therefore, even in the case in which a size of the semiconductor is decreased, a standardized ball layout may be used in the fan-out semiconductor package as it is, such that the fan-out semiconductor package may be mounted on the mainboard of the electronic device without using a separate BGA substrate, as described below.

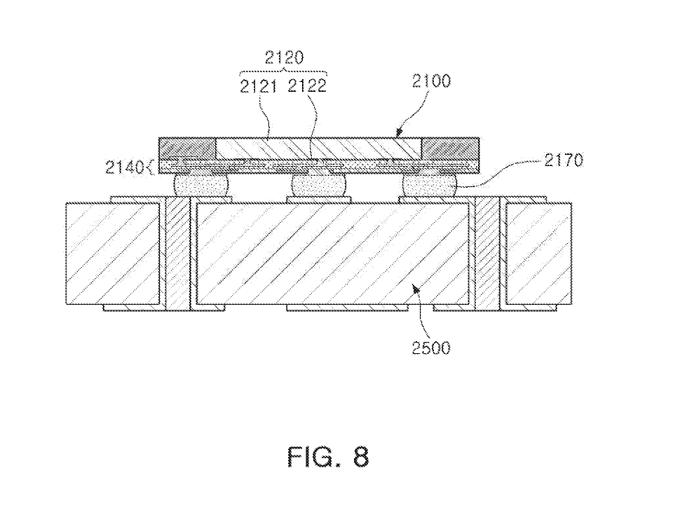

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor on the mainboard of the electronic device, or the like, as described above, and protecting the semiconductor from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

A fan-out sensor package according to the present disclosure may be manufactured using the fan-out semiconductor package technology described above. A fan-out sensor package according to the present disclosure will hereinafter be described with reference to the drawings.

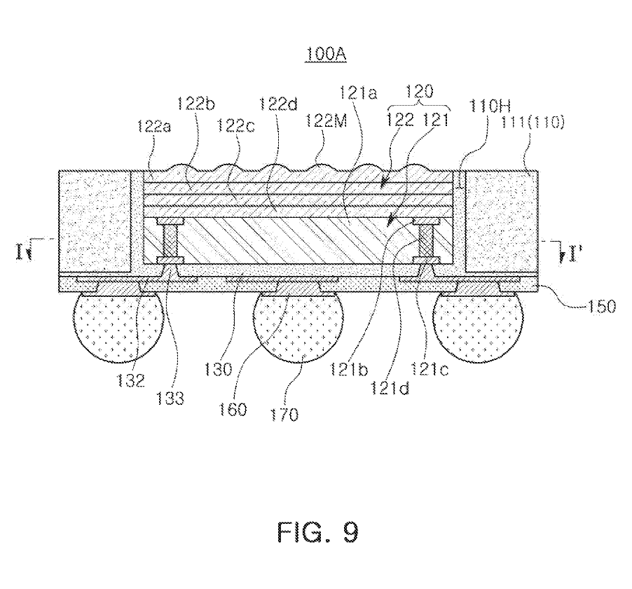

FIG. 9 is a schematic cross-sectional view illustrating an example of a fan-out sensor package.

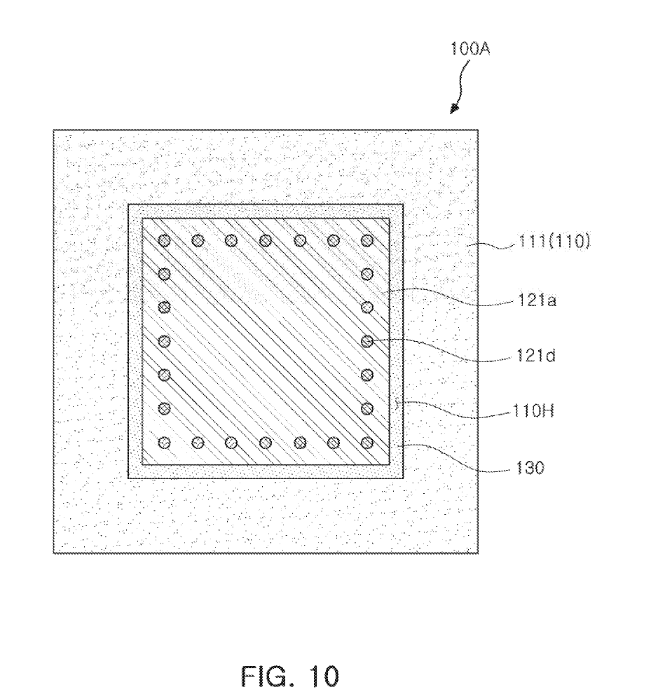

FIG. 10 is a schematic plan view taken along line I-I′ of the fan-out sensor package of FIG. 9.

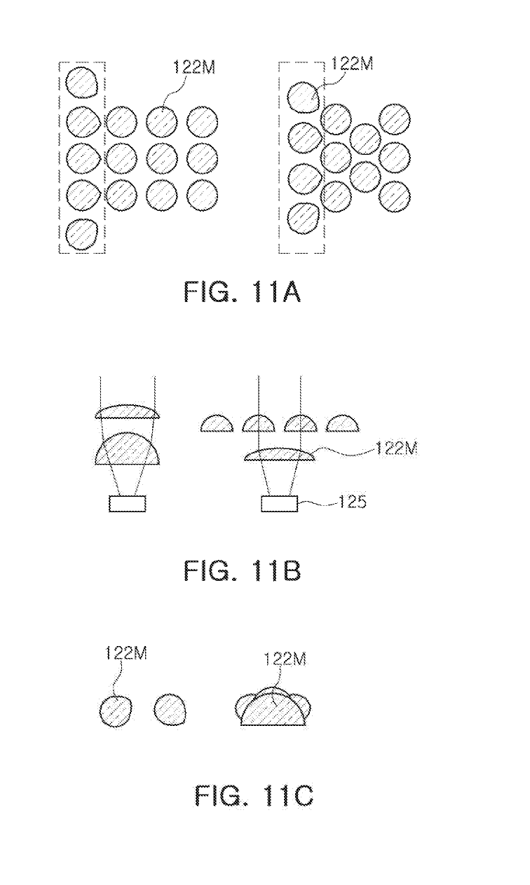

FIGS. 11A through 11C are schematic views illustrating lens disposition forms of an optical portion of the fan-out sensor package of FIG. 9.

Referring to FIGS. 9 through 11C, a fan-out sensor package 100A according to an exemplary embodiment in the present disclosure may include a core member 110 having a through-hole 110H, an image sensor chip 120 disposed in the through-hole 110H and including an integrated circuit (IC) 121 for an image sensor having a first surface having first connection pads 121b disposed thereon, a second surface opposing the first surface and having second connection pads 121c disposed thereon, and through-silicon-vias (TSVs) 121d penetrating between the first surface and the second surface and electrically connecting the first and second connection pads 121b and 121c to each other and an optical portion 122 disposed on the first surface of the IC 121 for an image sensor and having a plurality of lens layers 122a, 122b, 122c, and 122d, an encapsulant 130 covering at least portions of each of the core member 110 and the second surface of the IC 121 for an image sensor and filling at least portions of the through-hole 110H, a redistribution layer 132 disposed on the encapsulant 130, and vias 133 penetrating through at least portions of the encapsulant 130 and electrically connecting the redistribution layer 132 and the second connection pads 121c to each other. If necessary, the fan-out sensor package 100A may further include a passivation layer 150 disposed on the encapsulant 130 to cover the redistribution layer 132 and having openings exposing at least portions of the redistribution layer 132, an underbump metal layer 160 disposed in the openings of the passivation layer 150 and connected to the exposed redistribution layer 132, and electrical connection structures 170 disposed on the passivation layer 150 and connected to the underbump metal layer 160. In the exemplary embodiment, an upper surface of the core member 110, an upper surface of the encapsulant 130, and a portion of an upper surface of the optical portion 122 may be disposed on substantially the same level. The term “disposed on substantially the same level” conceptually includes being disposed on exactly the same level or being disposed on levels with a fine difference due to margins/variations in a process.

In a structure of an optical sensor package according to the related art, a BGA substrate is generally used. For example, the optical sensor package according to the related art has a form in which an image sensor is disposed on the BGA substrate, is electrically connected to the BGA substrate by bonding wires, and is then molded by a molding material. However, in this structure, a structure of the sensor package becomes complicated, and a size and a thickness of the sensor package are increased, due to the bonding wires disposed on the BGA substrate and the image sensor, an optical lens separately disposed on the image sensor, or the like. In addition, it is difficult to control a mold thickness, such that a complicated molding process is required. In addition, warpage of the sensor package greatly occurs due to an asymmetrical structure, such that a sensitivity of fingerprint sensing is decreased, and a yield at the time of mounting the sensor package on a circuit board, or the like, is decreased. In addition, the warpage of the sensor package generates a difficulty in stacking an infrared cut filter and a metal shield in a process of manufacturing the sensor package in a module form. As a method of solving these problems, a method of mounting an image sensor on a rigid-flex sub-board (for example, a rigid-flex printed circuit board (RFPCB)), performing wire bonding, and introducing a stiffener into a side portion is suggested. However, in this case, the number of assembling processes is many, and the assembling processes are complicated, such that occurrence of a defect may be increased, and the entire rigid-flex sub-board needs to be replaced at the time of the occurrence of the defect.

On the other hand, in the fan-out sensor package 100A according to the exemplary embodiment, the core member 110 having the through-hole 110H may be introduced, and the image sensor chip 120 may be disposed in the through-hole 110H to control a warpage problem of the fan-out sensor package 100A. In addition, the image sensor chip 120 may be implemented using a bonding structure between the IC 121 for an image sensor and the optical portion 122. In this case, the redistribution layer 132 may be introduced on the other surface of the encapsulant 130 opposing one surface of the encapsulant 130 on which the optical portion 122 is formed, and the TSVs 121d may be formed in the IC 121 for an image sensor to promote an electrical connection to the redistribution layer 132. Therefore, miniaturization and thinness of the fan-out sensor package 100A may be promoted, and performance of the fan-out sensor package 100A may be improved by securing a short signal path and sensing capability through exposure of a lens region. In addition, the encapsulant 130 may encapsulate the image sensor chip 120 so as not to cover the lens region of the optical portion 122. The upper surface of the core member 110, the upper surface of the encapsulant 130, and the portion of the upper surface of the optical portion 122 may be disposed on substantially the same level. Therefore, a process of attaching an optical member such as a lens or a filter is easy, such that a process of attaching and assembling the fan-out sensor package 100A to a display may be easy. Therefore, occurrence of voids is reduced, and assembling yield improvement and sensing characteristic improvement may thus be expected.

The respective components included in the fan-out sensor package 100A according to the exemplary embodiment will hereinafter be described below in more detail.

The core member 110 may improve rigidity of the fan-out sensor package 100A depending on certain materials, and serve to secure uniformity of a thickness of the encapsulant 130. The core member 110 may have the through-hole 110H. The image sensor chip 120 may be disposed in the through-hole 110H to be spaced apart from the core member 110 by a predetermined distance. Side surfaces of the image sensor chip 120 may be surrounded by the core member 110. A space between the core member 110 and the image sensor chip 120 in the through-hole 110H may be filled by the encapsulant 130, and the image sensor chip 120 may thus be surrounded by an insulating material, such that stability may be secured. However, such a form is only an example, and may be variously modified to have other forms, and the core member 110 may perform another function depending on such a form.

A material of an insulating layer 111 constituting the core member 110 is not particularly limited. For example, an insulating material may be used as the material of the insulating layer 111. In this case, the insulating material may be a thermosetting resin such as an epoxy resin, a thermoplastic resin such as a polyimide resin, a resin in which the thermosetting resin or the thermoplastic resin is impregnated in an inorganic filler or a core material such as a glass fiber (or a glass cloth or a glass fabric), for example, prepreg, Ajinomoto Build up Film (ABF), FR-4, Bismaleimide Triazine (BT), or the like. It may be advantageous in maintaining rigidity of the fan-out sensor package 100A to use prepreg including a glass fiber, an inorganic filler, and an insulating resin as the material of the insulating layer 111.

The image sensor chip 120 may have a bonding structure form between the IC 121 for an image sensor and the optical portion 122. The IC 121 for an image sensor may have a first surface of a body 121a having the first connection pads 121b disposed thereon, a second surface of the body 121a opposing the first surface and having the second connection pads 121c disposed thereon, and the TSVs 121d penetrating between the first surface and the second surface of the body 121a and electrically connecting the first and second connection pads 121b and 121c to each other. A base material of the body 121a may be silicon (Si), germanium (Ge), gallium arsenide (GaAs), or the like. Various circuits may be formed on the body 121a. That is, the IC 121 for an image sensor may be an IC type die manufactured by a wafer process. In more detail, the IC 121 for an image sensor may be IC 121 for an image sensor such as a complementary metal oxide semiconductor (CMOS) sensor type, a charge coupled device (CCD) sensor type, or the like, but is not limited thereto. The first and second connection pads 121b and 121c may electrically connect the image sensor chip 120 to other components, and may be formed of a conductive material such as aluminum (Al), copper (Cu), or the like. The TSVs 121d may be general TSVs. The optical portion 122 may have the plurality of lens layers 122a, 122b, 122c, and 122d. The lens layers 122a, 122b, 122c, and 122d may include micro lenses 122M. The micro lenses 122M may be arranged in order to collect light at an edge portion as illustrated in FIG. 11A, may be arranged in a layer form in order to improve light collection efficiency to a photodiode 125 as illustrated in FIG. 11B, or may have a shape for optimizing light collection at an edge portion or a shape for optimizing light collection per unit area as illustrated in FIG. 11C. Meanwhile, the optical portion 122 may be used in the fan-out sensor package 100A in such a manner in which it is bonded to the IC 121 for an image sensor without having an additional structure change.

The upper surface of the core member 110, the upper surface of the encapsulant 130, and the portion of the upper surface of the optical portion 122 may be disposed on substantially the same level. The term “substantially the same level” does not only mean that levels are completely the same as each other, but also means that a case in which a fine difference by a process exists is included. The reason is that the upper surface of the core member 110 and the upper surface of the optical portion 122 are encapsulated by the encapsulant 130 in a state in which they are attached together to an adhesive film 190, as seen from a process to be described below. In this way, a flat upper surface of the fan-out sensor package may be provided, and the process of assembling the fan-out sensor package to the display panel may thus be easier, as described above. Meanwhile, the adhesive film 190 is used to form the encapsulant 130, and occurrence of voids, a crack of a die, or the like, may be significantly reduced.

The encapsulant 130 may protect the core member 110, the image sensor chip 120, and the like. An encapsulation form of the encapsulant 130 is not particularly limited, but may be a form in which the encapsulant 130 surrounds at least portions of the core member 110, the image sensor chip 120, and the like. For example, the encapsulant 130 may cover at least portions of a lower surface of each of the core member 110 and the image sensor chip 120, and fill spaces between walls of the through-hole 110H and the side surfaces of the image sensor chip 120. Meanwhile, the encapsulant 130 may fill the through-hole 110H to thus serve as an adhesive and reduce buckling of the image sensor chip 120 depending on materials.

A material of the encapsulant 130 is not particularly limited. For example, the material of the encapsulant 130 may be prepreg including an insulating resin, a core material, a filler, and the like, or may be ABF including an insulating resin and a filler. If necessary, the material of the encapsulant 130 may be a photoimagable encapsulant (PIE) including a photosensitive insulating material. When the PIE is used as the material of the encapsulant 130, vias 133 to be described below may be formed in a fine pitch. Light noise introduced from an external source may be blocked using optical characteristics of the material of the encapsulant 130.

The redistribution layer 132 may serve to redistribute the first and second connection pads 121b and 122b. A material of the redistribution layer 132 may be a conductive material such as copper (Cu), aluminum (Al), silver (Ag), tin (Sn), gold (Au), nickel (Ni), lead (Pb), titanium (Ti), or alloys thereof. The redistribution layer 132 may perform various functions depending on a design of a corresponding layer. For example, the redistribution layer 132 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layer 132 may include via pads, electrical connection structures pads, and the like.

A surface treatment layer (not illustrated) may be formed on an exposed surface of the redistribution layer 132, if necessary. The surface treatment layer may be formed by, for example, electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like, but is not limited thereto.

The vias 133 may electrically connect the redistribution layer 132, the second connection pads 121c, and the like, formed on different layers to each other, resulting in an electrical path in the fan-out sensor package 100A. A material of each of the vias 133 may be a conductive material such as copper (Cu), aluminum (Al), silver (Ag), tin (Sn), gold (Au), nickel (Ni), lead (Pb), titanium (Ti), or alloys thereof. Each of the vias 133 may be completely filled with the conductive material, or the conductive material may also be formed along a wall of each of the vias. In addition, each of the vias 133 may have any shape known in the related art such as a tapered shape.

Meanwhile, although not illustrated in detail in the drawings, the redistribution layer 132 and the vias 133 may also be implemented in a multilayer form having a larger number of layers. In this case, a separate insulating layer such as a PID or an ABF may further be stacked on the encapsulant 130. That is, a larger number of redistribution layers 132 and vias 133 may be formed depending on a wiring design.

The passivation layer 150 may be additionally configured to protect the redistribution layer 132 from external physical or chemical damage. The passivation layer 150 may have the openings exposing at least portions of the redistribution layer 132. The number of openings formed in the passivation layer 150 may be several tens to several thousands. A material of the passivation layer 150 is not particularly limited. For example, the material of the passivation layer 150 may be prepreg including an insulating resin, a core material, a filler, and the like, or may be ABF including an insulating resin and a filler. Alternatively, any known solder resist maybe used as the material of the passivation layer 150.

The underbump metal layer 160 may be additionally configured to improve connection reliability of the electrical connection structures 170 to improve board level reliability of the fan-out sensor package 100A. The underbump metal layer 160 may be connected to the redistribution layer 132 exposed through the openings of the passivation layer 150. The underbump metal layer 160 may be formed in the openings of the passivation layer 150 by any known metallization method using any known conductive material such as a metal, but is not limited thereto.

The electrical connection structure 170 may be additionally configured to physically or electrically externally connect the fan-out sensor package 100A. For example, the fan-out sensor package 100A may be mounted on the mainboard of the electronic device through electrical connection structures 170. Each of the electrical connection structures 170 may be formed of a low melting point metal, for example, a solder including tin (Sn). However, this is only an example, and a material of each of the electrical connection structures 170 is not particularly limited thereto. Each of the electrical connection structures 170 may be a land, a ball, a pin, or the like. The electrical connection structures 170 may be formed as a multilayer or single layer structure. When the electrical connection structures 170 are formed as a multilayer structure, the electrical connection structures 170 may include a copper (Cu) pillar and a solder. When the electrical connection structures 170 are formed as a single layer structure, the electrical connection structures 170 may include a tin-silver solder or copper (Cu). However, this is only an example, and the electrical connection structures 170 are not limited thereto.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several millions according to the numbers of first and second connection pads 121b and 121c, or may be provided in an amount of several tens to several millions or more or several tens to several millions or less. When the electrical connection structures 170 are solder balls, the electrical connection structures 170 may cover side surfaces of the underbump metal layer 160 extending onto one surface of the passivation layer 150, and connection reliability may be more excellent.

At least one of the electrical connection structures 170 may be disposed in a fan-out region. The fan-out region refers to a region except for the region in which the image sensor chip 120 is disposed. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be manufactured to have a small thickness, and may have price competitiveness.

Meanwhile, a metal thin film may be formed on the walls of the through-hole 110H, if necessary, in order to dissipate heat or block electromagnetic waves. In addition, a separate surface mounting component may be disposed on a surface of the passivation layer 150.

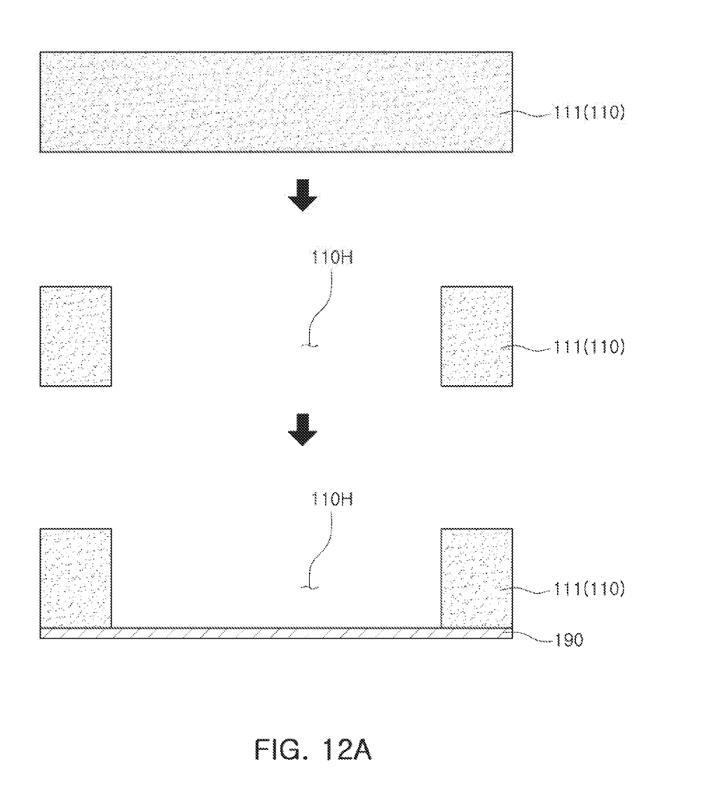

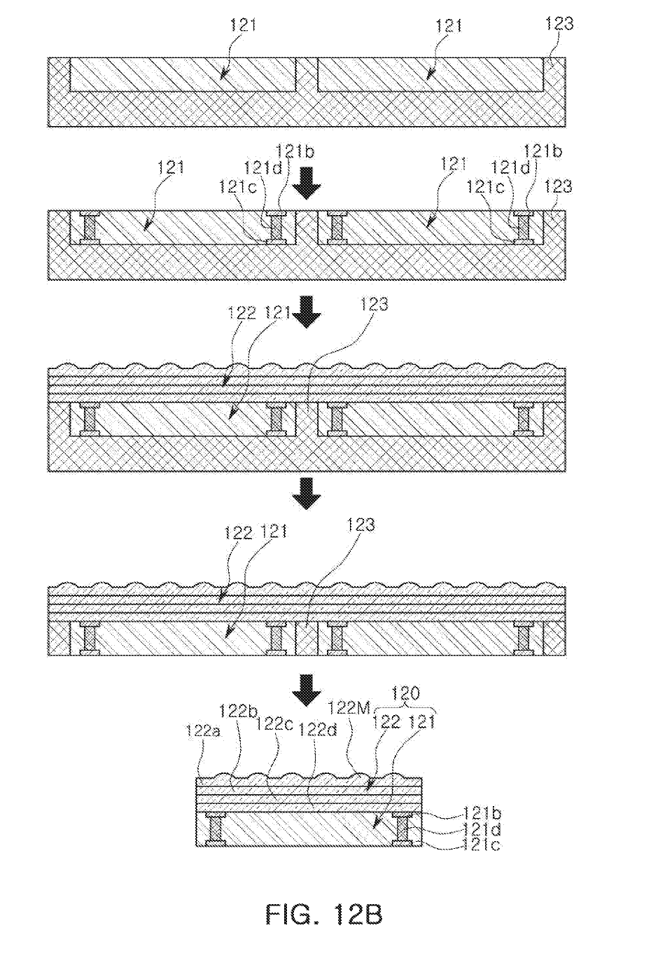

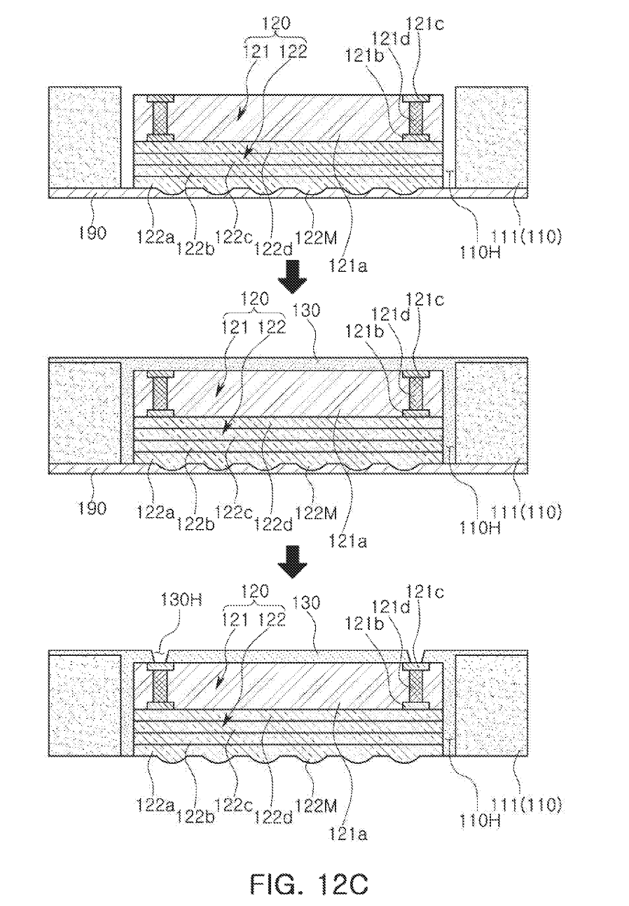

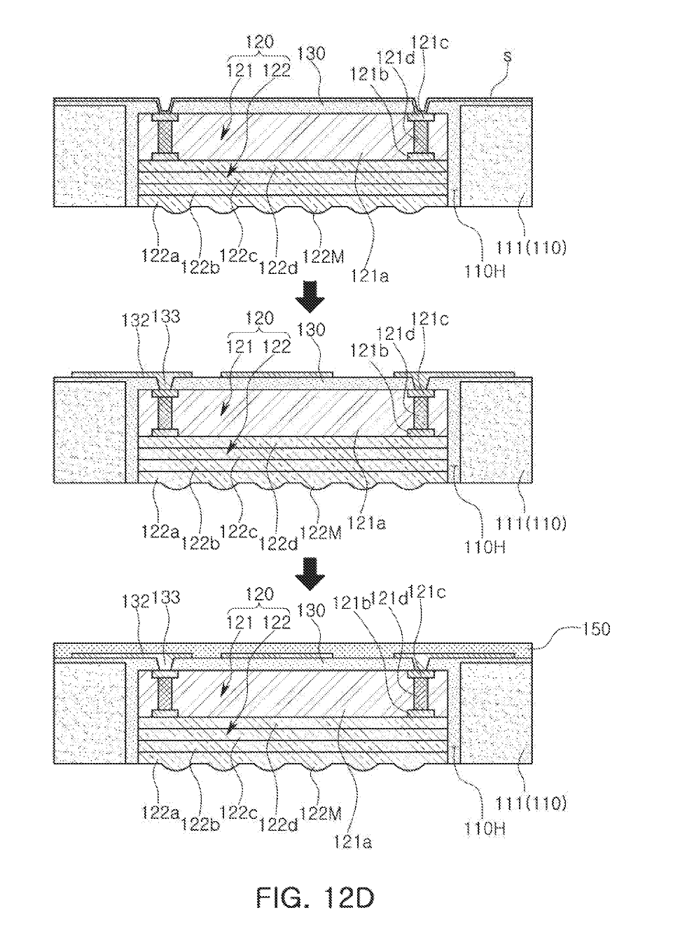

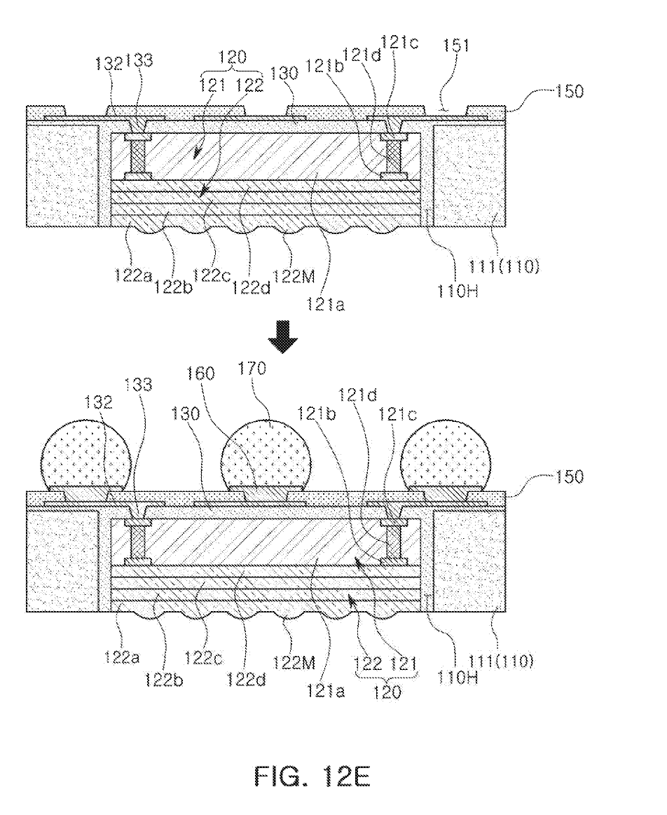

FIGS. 12A through 12E are schematic views illustrating an example of processes of manufacturing the fan-out sensor package of FIG. 9.

Referring to FIG. 12A, the core member 110 may be first prepared. The core member 110 may be prepared using an unclad copper clad laminate (CCL). Then, the through-hole 110H may be formed in the core member 110. The through-hole 110H may be formed using a laser drill and/or a mechanical drill or be formed by a sandblast. Then, the adhesive film 190 may be attached to a lower surface of the core member 110. The adhesive film 190 may be any known tape including an epoxy resin, or the like.

Referring to FIG. 12B, the image sensor chip 120 may be prepared. The image sensor chip 120 may be prepared by forming a plurality of ICs 121a for an image sensor on a wafer 123, forming TSVs 121d in the respective ICs 121a for an image sensor, attaching the optical portion 122 to the plurality of ICs 121a for an image sensor, grinding the wafer by a backside grinding process, and perform a dicing process to obtain a plurality of image sensor chips 120.

Then, referring to FIG. 12C, the image sensor chip 120 may be attached to a portion of the adhesive film 190 exposed through the through-hole 110H. The image sensor chip 120 may be disposed so that the optical portion 122 is attached to the adhesive film 190. Then, the image sensor chip 120 may be encapsulated using the encapsulant 130. The encapsulant 130 may be formed by any known lamination method or an applying and hardening method. After the encapsulant 130 is formed, the adhesive film 190 may be removed. However, if necessary, the adhesive film 190 may also be removed later. Then, via holes 130H may be formed in the encapsulant 130 using the second connection pads 121c as stoppers. The via holes 130H may be formed by a photolithography method when the encapsulant 130 includes a photosensitive insulating material, and may be formed by a laser method when the encapsulant 130 includes a non-photosensitive insulating material.

Then, referring to FIG. 12D, a seed layer s may be formed using sputter, chemical copper plating, or the like. Then, patterning may be attempted using a dry film (not illustrated), or the like, a plating process such as electroplating, electroless plating, or the like, may be performed using the seed layer s, and the seed layer s remaining in a region in which patterns are not formed may be removed by an etching process. Resultantly, the redistribution layer 132 and the vias 133 may be formed. Then, the passivation layer 150 covering the redistribution layer 132 may be formed on the encapsulant 130 by a lamination method or an applying and hardening method, if necessary.

Then, referring to FIG. 12E, the openings 151 exposing at least portions of the redistribution layer 132 may be formed in the passivation layer 150, if necessary. The openings 151 may be formed using a laser drill, but may also be formed by a photolithography method depending on a material of the passivation layer 150. Then, the underbump metal layer 160 and the electrical connection structures 170 may be formed, if necessary. A series of processes may be performed on a panel level. In this case, when a singulation process is performed, a plurality of fan-out sensor packages 100A may be obtained.

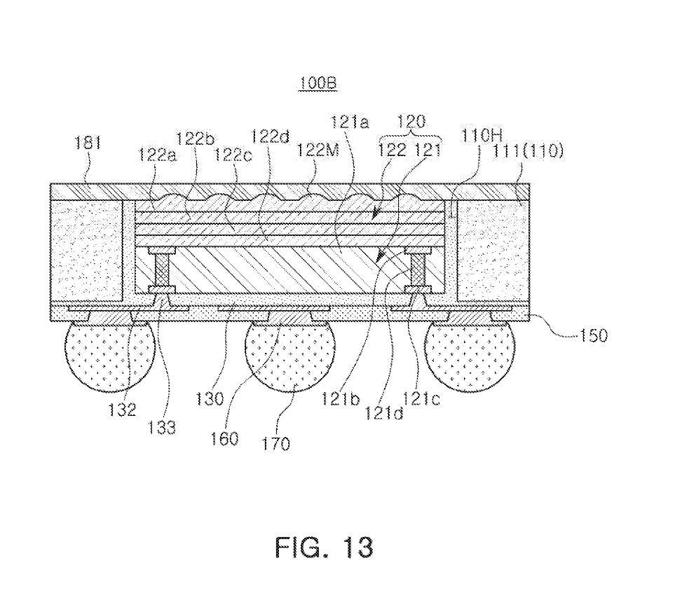

FIG. 13 is a schematic cross-sectional view illustrating another example of a fan-out sensor package.

Referring to FIG. 13, a fan-out sensor package 100B according to another exemplary embodiment in the present disclosure may further include an optical member 181 disposed on a core member 110 and an optical portion 122. The optical member 181 may be a lens such as a glass, or be an optical filter. Alternatively, the optical member 181 may have a form in which both of the lens and the optical filter are stacked. The optical filter may be an infrared cut filter. Other contents overlap those described above, and a detailed description thereof is thus omitted.

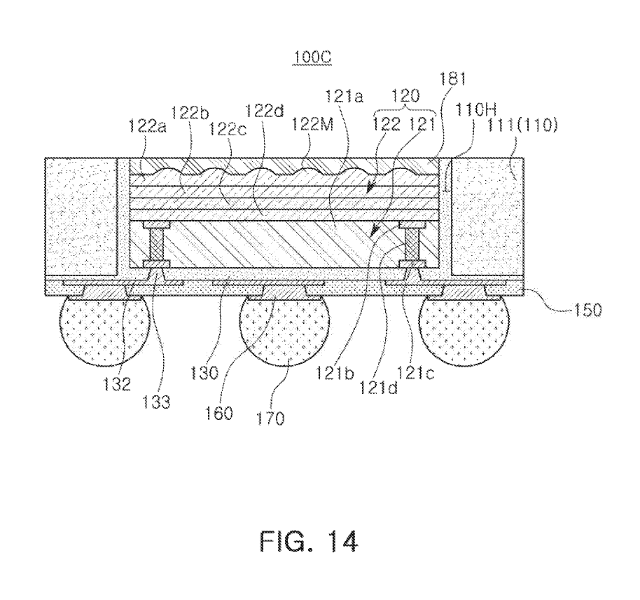

FIG. 14 is a schematic cross-sectional view illustrating another example of a fan-out sensor package.

Referring to FIG. 14, a fan-out sensor package 100C according to another exemplary embodiment in the present disclosure may further include an optical member 181 disposed on an optical portion 122. In this case, the optical member 181 may have a size similar to that of an image sensor chip 120, is not disposed on a core member 110, but may be disposed in a through-hole 110H of the core member 110, and may be at least partially encapsulated by an encapsulant 130. The optical member 181 may be introduced by attaching optical members 181 to optical portions 122 using an adhesive at the time of preparing image sensor chips 120 and then performing a dicing process, or the like. An upper surface of the core member 110, an upper surface of the encapsulant 130, and an upper surface of the optical member 181 may be disposed on substantially the same level. Other contents overlap those described above, and a detailed description thereof is thus omitted.

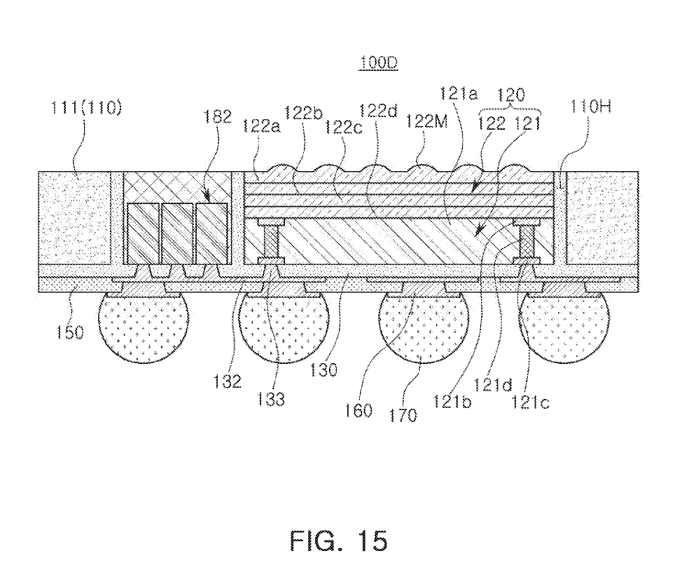

FIG. 15 is a schematic cross-sectional view illustrating another example of a fan-out sensor package.

Referring to FIG. 15, a fan-out sensor package 100D according to another exemplary embodiment in the present disclosure may further include a light emitting element 182 disposed side-by-side with an image sensor chip 120 in a through-hole 110H of a core member 110. The light emitting element 182 may be at least partially encapsulated by an encapsulant 130, and may be electrically connected to a redistribution layer 132 through vias 133. In addition, the light emitting element 182 may also be electrically connected to the image sensor chip 120 through the redistribution layer 132. The light emitting element may be a micro light emitting diode (LED), or the like, and when a light source is embedded in the fan-out sensor package 100D as described above, a light recognition rate may be improved. The light emitting element 182 may have a wafer bare die form. An upper surface of the light emitting element 182 may be disposed on a level that is substantially the same as that of an upper surface of the core member 110, a portion of an upper surface of an optical portion 122, and an upper surface of the encapsulant 130. The term “substantially the same” does not only mean that levels are completely the same as each other, but also means that a case in which a fine difference by a process exists is included. Other contents overlap those described above, and a detailed description thereof is thus omitted.

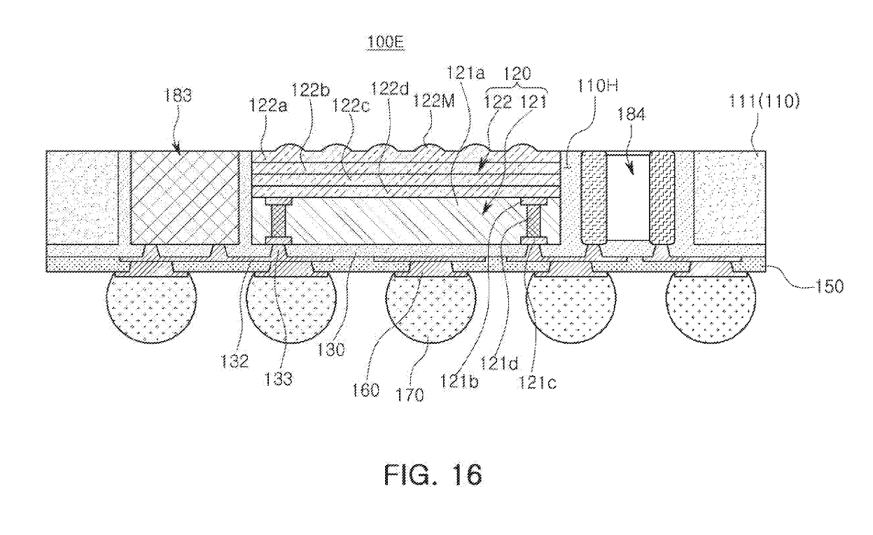

FIG. 16 is a schematic cross-sectional view illustrating another example of a fan-out sensor package.

Referring to FIG. 16, a fan-out sensor package 100E according to another exemplary embodiment in the present disclosure may further include a control integrated circuit 183 and a passive component 184 disposed side-by-side with an image sensor chip 120 in a through-hole 110H of a core member 110. At least portions of each of the control integrated circuit 183 and the passive component 184 may be encapsulated by an encapsulant 130. The control integrated circuit 183 and the passive component 184 may be electrically connected to a redistribution layer 132 through vias 133, and may be electrically connected to the image sensor chip 120 through the redistribution layer 132. A signal or power transmission path and noise may be significantly reduced through such a disposition. The control integrated circuit 183 may have a wafer bare die form. The passive component 184 may be any known passive component such as a capacitor, an inductor, a beads, or the like. An upper surface of the control integrated circuit 183 and/or the passive component 184, a portion of an upper surface of an optical portion 122, and an upper surface of the encapsulant 130 may be disposed on substantially the same level. The term. “substantially the same level” does not only mean that levels are completely the same as each other, but also means that a case in which a fine difference by a process exists is included. Other contents overlap those described above, and a detailed description thereof is thus omitted.

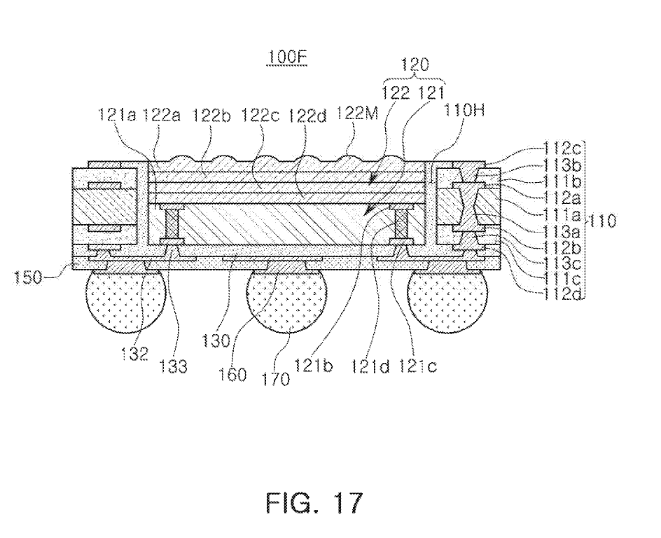

FIG. 17 is a schematic cross-sectional view illustrating another example of a fan-out sensor package.

Referring to FIG. 17, in a fan-out sensor package 100F according to another exemplary embodiment in the present disclosure, a core member 110 may include a plurality of wiring layers 112a, 112b, 112c, and 112d. In detail, the core member 110 may include a first insulating layer 111a, a first wiring layer 112a and a second wiring layer 112b disposed on opposite surfaces of the first insulating layer 111a, respectively, a second insulating layer 111b disposed on the first insulating layer 111a and covering the first wiring layer 112a, a third wiring layer 112c disposed on the second insulating layer 111b, a third insulating layer 111c disposed on the first insulating layer 111a and covering the second wiring layer 112b, and a fourth wiring layer 112d disposed on the third insulating layer 111c. In addition, the core member 110 may include first vias 113a penetrating through the first insulating layer 111a and electrically connecting the first and second wiring layers 112a and 112b to each other, second vias 113b penetrating through the second insulating layer 111b and electrically connecting the first and third wiring layers 112a and 112c to each other, and third vias 113c penetrating through the third insulating layer 111c and electrically connecting the second and fourth wiring layers 112b and 112d to each other. Since the core member 110 may include a large number of wiring layers 112a, 112b, 112c, and 112d, a redistribution layer 132 may further be simplified. The plurality of wiring layers 112a, 112b, 112c, and 112d may be electrically connected to first and second connection pads 121b and 121c of an image sensor chip 120 through the redistribution layer 132.

A material of each of the insulating layers 111a, 111b, and 111c is not particularly limited. For example, an insulating material may be used as the material of each of the insulating layers 111a, 111b, and 111c. In this case, the insulating material may be a thermosetting resin such as an epoxy resin, a thermoplastic resin such as a polyimide resin, a resin in which the thermosetting resin or the thermoplastic resin is impregnated in an inorganic filler or a core material such as a glass fiber (or a glass cloth or a glass fabric), for example, prepreg, ABF, FR-4, BT, or the like. Alternatively, a PID resin may also be used as the insulating material.

The wiring layers 112a, 112b, 112c, and 112d may serve to redistribute the connection pads 121b and 121c of the image sensor chip 120. A material of each of the wiring layers 112a, 112b, 112c, and 112d may be a conductive material such as copper (Cu), aluminum (Al), silver (Ag), tin (Sn), gold (Au), nickel (Ni), lead (Pb), titanium (Ti), or alloys thereof. The wiring layers 112a, 112b, 112c, and 112d may perform various functions depending on designs of corresponding layers. For example, the wiring layers 112a, 112b, 112c, and 112d may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a, 112b, 112c, and 112d may include via pads, electrical connection structures pads, and the like.

The vias 113a, 113b, and 113c may electrically connect the wiring layers 112a, 112b, 112c, and 112d formed on different layers to each other, resulting in an electrical path in the core member 110. A material of each of the vias 113a, 113b, and 113c may be a conductive material. Each of the vias 113a, 113b, and 113c may be completely filled with the conductive material, or the conductive material may also be formed along a wall of each of via holes. The first vias 113a may have a hourglass shape, and the second and third vias 113b and 113c may have tapered shapes of which directions are opposite to each other. However, the first to third vias 113a, 113b, and 113c are not limited thereto.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, an inorganic filler, and an insulating resin, and the second insulating layer 111b and the third insulating layer 111c may be an ABF or a photosensitive insulating film including an inorganic filler and an insulating resin. However, the materials of the first insulating layer 111a and the second and third insulating layers 111b and 111c are not limited thereto.

The first wiring layer 112a and the second wiring layer 112b may be disposed at a level between an upper surface and a lower surface of the image sensor chip 120. A thickness of each of the wiring layers 112a, 112b, 112c, and 112d may be greater than that of the redistribution layer 132. Other contents overlap those described above, and a detailed description thereof is thus omitted. Meanwhile, the contents of the fan-out sensor packages 100B to 100E described above may also be applied to the fan-out sensor package 100F according to another exemplary embodiment described above. That is, the contents described in the respective exemplary embodiments may be combined with each other without being contradicted.

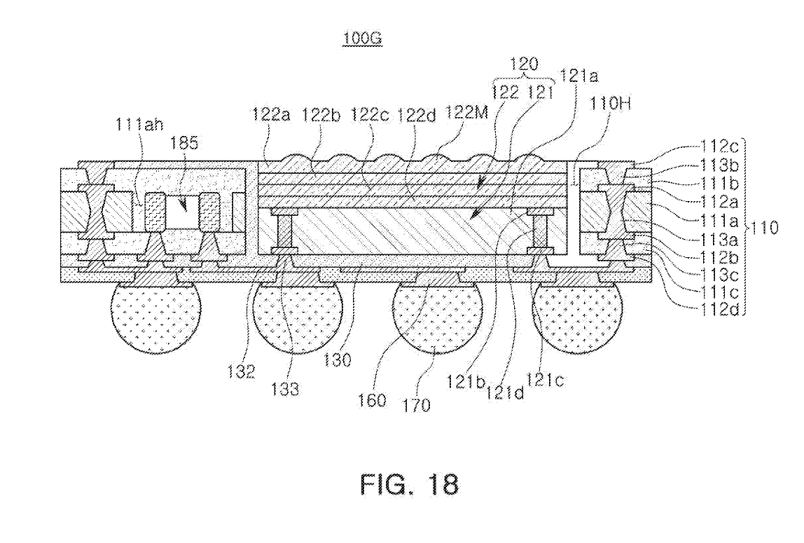

FIG. 18 is a schematic cross-sectional view illustrating another example of a fan-out sensor package.

Referring to FIG. 18, a fan-out sensor package 100G according to another exemplary embodiment may be substantially the same as the fan-out sensor package 100F according to another exemplary embodiment described above except that it further includes a passive component 185 embedded in a cavity 111ah penetrating through a first insulating layer 111a of a core member 110. The passive component 185 may be electrically connected to a fourth wiring layer 112d through third vias 113c. The passive component 185 may be any known passive component such as a capacitor, an inductor, a beads, or the like. The passive component 185 may be encapsulated by a second insulating layer 111b. The passive component 185 may also be electrically connected to an image sensor chip 120 through a redistribution layer 132. Other contents overlap those described above, and a detailed description thereof is thus omitted. Meanwhile, the contents of the fan-out sensor packages 100B to 100E described above may also be applied to the fan-out sensor package 100G according to another exemplary embodiment described above. That is, the contents described in the respective exemplary embodiments may be combined with each other without being contradicted.

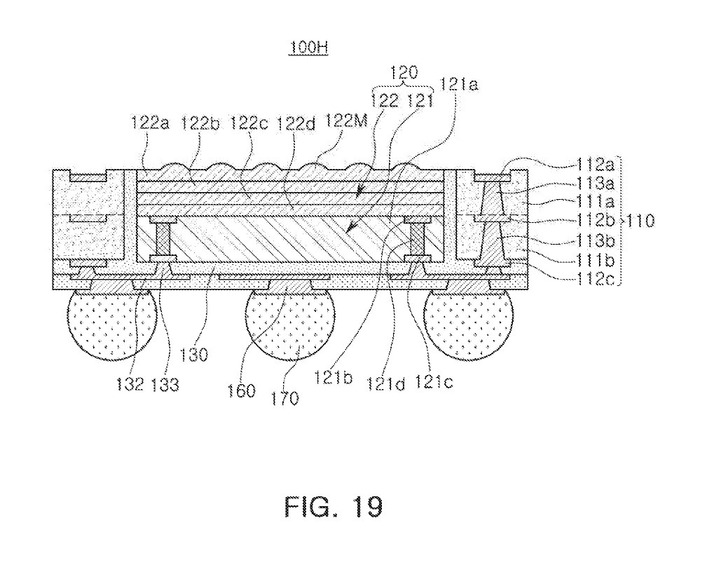

FIG. 19 is a schematic cross-sectional view illustrating another example of a fan-out sensor package.

Referring to FIG. 19, in a fan-out sensor package 100H according to another exemplary embodiment in the present disclosure, a core member 110 may include a plurality of wiring layers 112a, 112b, and 112c. In detail, the core member 110 may include a first insulating layer 111a, a first wiring layer 112a embedded in the first insulating layer 111a so that an upper surface thereof is exposed, a second wiring layer 112b disposed on the other surface of the first insulating layer 111a opposing one surface of the first insulating layer 111a in which the first wiring layer 112a is embedded, a second insulating layer 111b disposed on the first insulating layer 111a and covering the second wiring layer 112b, and a third wiring layer 112c disposed on the second insulating layer 111b. In addition, the core member 110 may include first vias 113a penetrating through the first insulating layer 111a and electrically connecting the first and second wiring layers 112a and 112b to each other and second vias 113b penetrating through the second insulating layer 111b and electrically connecting the second and third wiring layers 112b and 112c to each other. Likewise, since the core member 110 may include a large number of wiring layers 112a, 112b, and 112c, a redistribution layer 132 may be simplified. The plurality of wiring layers 112a, 112b, and 112c may be electrically connected to first and second connection pads 121b and 121c of an image sensor chip 120 through the redistribution layer 132.

A material of each of the insulating layers 111a and 111b is not particularly limited. For example, an insulating material may be used as the material of each of the insulating layers 111a and 111b. In this case, the insulating material may be a thermosetting resin such as an epoxy resin, a thermoplastic resin such as a polyimide resin, a resin in which the thermosetting resin or the thermoplastic resin is impregnated in an inorganic filler or a core material such as a glass fiber (or a glass cloth or a glass fabric), for example, prepreg, ABF, FR-4, BT, or the like. Alternatively, a PID resin may also be used as the insulating material.

The wiring layers 112a, 112b, and 112c may serve to redistribute the connection pads 121b and 121c of the image sensor chip 120. A material of each of the wiring layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The wiring layers 112a, 112b, and 112c may perform various functions depending on designs of corresponding layers. For example, the wiring layers 112a, 112b, and 112c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a, 112b, and 112c may include via pads, electrical connection structures pads, and the like.

The vias 113a and 113b may electrically connect the wiring layers 112a, 112b, and 112c formed on different layers to each other, resulting in an electrical path in the core member 110. A material of each of the vias 113a and 113b may be a conductive material. Each of the vias 113a and 113b may be completely filled with a conductive material, or a conductive material may also be formed along a wall of each of via holes. In addition, the vias 113a and 113b may have tapered shapes of which directions are the same as each other, but are not limited thereto.

The first wiring layer 112a may be recessed into the first insulating layer 111a. That is, an upper surface of the first wiring layer 112 may have a step with respect to an upper surface of the first insulating layer 111a in FIG. 19. The second wiring layer 112a may be disposed at a level between an upper surface and a lower surface of the image sensor chip 120. A thickness of each of the wiring layers 112a, 112b, and 112c of the core member 110 may be greater than that of the redistribution layer 132. Other contents overlap those described above, and a detailed description thereof is thus omitted. Meanwhile, the contents of the fan-out sensor packages 100B to 100E described above may also be applied to the fan-out sensor package 100H according to another exemplary embodiment described above. That is, the contents described in the respective exemplary embodiments may be combined with each other without being contradicted.

As set forth above, according to the exemplary embodiment in the present disclosure, an optical fan-out sensor package in which assembling yield improvement and sensing characteristic improvement may be expected since a process of attaching an optical member such as a lens or a filter to an upper end of the fan-out sensor package is easy and a process of attaching and assembling the fan-out sensor package to a display is thus easy and thinness of the fan-out sensor package utilizing a bonding structure between an optical portion and an IC for an image sensor and miniaturization of the fan-out sensor package through a redistribution design utilizing TSVs may be expected may be provided.

While exemplary embodiments have been shown and described above, it will be apparent to those skilled in the art that modifications and variations could be made without departing from the scope of the present invention as defined by the appended claims.

What is claimed is:

1. A fan-out sensor package comprising:
an image sensor chip including an integrated circuit (IC) for an image sensor having a first surface having first connection pads disposed thereon, a second surface opposing the first surface and having second connection pads disposed thereon, and through-silicon-vias (TSVs) penetrating between the first surface and the second surface and electrically connecting the first and second connection pads to each other and an optical portion disposed on the first surface of the IC for an image sensor and having a plurality of lens layers;
an encapsulant covering at least portions of the second surface of the IC for an image sensor;
a redistribution layer disposed on the encapsulant; and
vias penetrating through at least portions of the encapsulant and electrically connecting the redistribution layer and the second connection pads to each other.

2. The fan-out sensor package of claim 1, further comprising a core member having a through-hole,
wherein the image sensor chip is disposed in the through-hole, and
the encapsulant fills at least portions of the through-hole.

3. The fan-out sensor package of claim 2, wherein an upper surface of the core member, an upper surface of the encapsulant, and a portion of an upper surface of the optical portion are disposed on substantially the same level.

4. The fan-out sensor package of claim. 3, wherein lens of the plurality of lens layers protrude from substantially the same level on which the upper surface of the core member, the upper surface of the encapsulant, and the portion of the upper surface of the optical portion are disposed.

5. The fan-out sensor package of claim 2, further comprising an optical member disposed on the core member and the optical portion.

6. The fan-out sensor package of claim 2, further comprising an optical member disposed on the optical portion,
wherein the optical member is disposed in the through-hole.

7. The fan-out sensor package of claim 6, wherein an upper surface of the core member, an upper surface of the encapsulant, and an upper surface of the optical member are disposed on substantially the same level.

8. The fan-out sensor package of claim 2, further comprising a light emitting element disposed side-by-side with the image sensor chip in the through-hole,
wherein the encapsulant encapsulates at least portions of the light emitting element, and
the light emitting element is electrically connected to the redistribution layer through the vias.

9. The fan-out sensor package of claim 8, wherein the light emitting element is a micro light emitting diode (LED).

10. The fan-out sensor package of claim 2, further comprising a control integrated circuit disposed side-by-side with the image sensor chip in the through-hole,
wherein the encapsulant encapsulates at least portions of the control integrated circuit, and
the control integrated circuit is electrically connected to the redistribution layer through the vias.

11. The fan-out sensor package of claim 10, further comprising a passive component disposed side-by-side with the image sensor chip in the through-hole,
wherein the encapsulant encapsulates at least portions of the passive component, and
the passive component is electrically connected to the redistribution layer through the vias.

12. The fan-out sensor package of claim 2, wherein the core member includes a first insulating layer and a first wiring layer and a second wiring layer disposed on opposite surfaces of the first insulating layer, respectively, and
the first and second wiring layers are electrically connected to the redistribution layer.

13. The fan-out sensor package of claim 12, wherein the core member further includes a second insulating layer disposed on the first insulating layer and covering the first wiring layer, a third wiring layer disposed on the second insulating layer, a third insulating layer disposed on the first insulating layer and covering the second wiring layer, and a fourth wiring layer disposed on the third insulating layer, and
the third and fourth wiring layers are electrically connected to the redistribution layer.

14. The fan-out sensor package of claim 13, further comprising a passive component embedded in a cavity penetrating through the first insulating layer,
wherein the passive component is electrically connected to the fourth wiring layer through the vias.

15. The fan-out sensor package of claim 2, wherein the core member includes a first insulating layer, a first wiring layer embedded in the first insulating layer and having one surface thereof exposed from the first insulating layer, a second wiring layer disposed on the other surface of the first insulating layer opposing the one surface of the first insulating layer in which the first wiring layer is embedded, a second insulating layer disposed on the first insulating layer and covering the second wiring layer, and a third wiring layer disposed on the second insulating layer, and
the first to third wiring layers are electrically connected to the redistribution layer.

16. The fan-out sensor package of claim 1, wherein the image sensor chip is in a complementary metal oxide semiconductor (CMOS) image sensor (CIS) type.

17. The fan-out sensor package of claim 1, wherein the encapsulant includes a photosensitive insulating material.

18. The fan-out sensor package of claim 1, wherein the encapsulant does not cover an upper surface of the image sensor chip.
